(19) United States
(12) Patent Application Publication
(10) Pub. No.: US 2011/0221059 A1
(43) Pub. Date: Sep. 15, 2011

(54) QUAD FLAT NON-LEADED SEMICONDUCTOR PACKAGE AND METHOD OF FABRICATING THE SAME

(75) Inventors: Fu-Di Tang, Taichung Hsien (TW); Ching-Chiuan Wei, Taichung (TW); Yung-Chih Lin, Taichung (TW)

(73) Assignee: SILICONWARE PRECISION INDUSTRIES CO., LTD., Taichung (TW)

(21) Appl. No.: 12/825,513

(22) Filed: Jun. 29, 2010

(30) Foreign Application Priority Data
Mar. 12, 2010 (TW) 099107208

(51) Int. Cl. H01L 23/49; H01L 21/60

(52) U.S. Cl. 257/738; 438/124; 257/741; 257/784; 257/E21.504; 257/E21.509; 257/E23.023; 257/E23.024

(57) ABSTRACT

A QFN package includes a chip-mounting base; electrically connecting pads disposed around the periphery of the chip-mounting base, the bottom surfaces of the chip-mounting base and the electrically connecting pads being covered by a copper layer; a chip mounted on the top surface of the chip-mounting base; bonding wires electrically connecting to the chip and the electrically connecting pads; an encapsulant encapsulating the chip-mounting base, the electrically connecting pads, the chip and the bonding wires while exposing the copper layer; and a dielectric layer formed on the bottom surfaces of the encapsulant and the copper layer and having a plurality of openings exposing a portion of the copper layer. The copper layer has good bonding with the dielectric layer that helps to prevent solder material in a reflow process from permeating into the interface between the chip-mounting base, the electrically connecting pads and the dielectric layer, thereby avoiding solder extrusion and enhancing product yield.

### BACKGROUND OF THE INVENTION

1. Field of the Invention

The present invention relates generally to quad flat non-leaded (QFN) semiconductor packages, and more particularly, to a QFN semiconductor package capable of preventing solder extrusion and a method for fabricating the same.

2. Description of Related Art

In a QFN semiconductor package having a chip-mounting base and a plurality of leads, the bottom surfaces of the chip-mounting base and the leads are exposed from the semiconductor package such that the semiconductor package can be coupled to a printed circuit board through surface mount techniques, thereby forming a circuit module with a specific function. During such a surface mount process, the chip-mounting base and leads of the QFN semiconductor package are directly soldered to the printed circuit board.

As disclosed by U.S. Pat. No. 6,238,952, No. 6,261,864 and No. 6,306,685, a conventional QFN semiconductor package 7 and a method for fabricating the same is shown in FIG. 7.

The QFN semiconductor package 7 comprises: a lead frame 71 having a chip-mounting base 711 and a plurality of leads 713; a chip 73 mounted on the chip-mounting base 711; a plurality of bonding wires 74 electrically connecting to the chip 73 and the leads 713; and an encapsulant 75 encapsulating the chip 73, the bonding wires 74 and the lead frame 71, wherein the chip-mounting base 711 and the leads 713 protrude from the encapsulant 75 since the chip-mounting base 711 and the leads 713 are directly formed from a metal carrier by etching. Although such a method increases the number of I/O connections, it cannot form complex conductive traces.

FIGS. 8A to 8C′ show another conventional QFN semiconductor package 8 and a method for fabricating the same as disclosed in U.S. Pat. No. 5,830,800 and No. 6,635,957. Referring to FIGS. 8A to 8C′, a plurality of leads 813 is formed on a metal carrier 80 by electroplating, wherein the leads 813 may be made of Au//Pd/Ni/Pd or Pd/Ni/Au; then, a plurality of chips 83 is mounted on the leads 813; the chips 83 are electrically connected to the leads 813 through a plurality of bonding wires 84, respectively, and an encapsulant 85 is formed; thereafter, the carrier 80 is removed and a dielectric layer 86 is formed on the bottom surface of the encapsulant 85 and has a plurality of openings 861 formed therein such that a plurality of solder balls 87 can be mounted on the leads 813 exposed through the openings 861. However, since the solder balls 87 have good wetting ability on a gold layer or a palladium layer while the bonding between the dielectric layer 96 and the gold layer or palladium layer is quite poor, solder material can easily permeate into the interface between the leads 813 and the dielectric layer 86, thereby resulting in occurrence of solder extrusion 862 that prevents formation of solder balls and even causes short circuits between adjacent solder balls. As such, subsequent SMT processes are adversely affected, the fabrication cost is increased and the product yield is decreased.

Therefore, it is imperative to overcome the above drawbacks of the prior art.

### SUMMARY OF THE INVENTION

In view of the above drawbacks of the prior art, the present invention provides a method for fabricating a QFN semiconductor package, which comprises the steps of: providing a carrier and forming on the carrier a chip-mounting base and a plurality of electrically connecting pads disposed around the periphery of the chip-mounting base; mounting a chip on the top surface of the chip-mounting base; electrically connecting the chip and the electrically connecting pads through a plurality of bonding wires; forming an encapsulant on the carrier to encapsulate the chip-mounting base, the electrically connecting pads, the chip and the bonding wires; removing the carrier to expose the bottom surfaces of the chip-mounting base and the electrically connecting pads; forming a copper layer to cover the exposed bottom surfaces of the chip-mounting base and the electrically connecting pads; and forming a dielectric layer on the bottom surfaces of the encapsulant and the copper layer and forming a plurality of openings in the dielectric layer for exposing a portion of the copper layer.

According to the above-described method, the present invention further provides a QFN semiconductor package, which comprises: a chip-mounting base; a plurality of electrically connecting pads disposed around the periphery of the chip-mounting base, the bottom surfaces of the chip-mounting base and the electrically connecting pads being covered by a copper layer; a chip mounted on the top surface of the chip-mounting base; a plurality of bonding wires electrically connecting to the chip and the electrically connecting pads; an encapsulant encapsulating the chip-mounting base, the electrically connecting pads, the chip and the bonding wires while exposing the copper layer on the bottom surfaces of the chip-mounting base and the electrically connecting pads; and a dielectric layer formed on the bottom surfaces of the encapsulant and the copper layer and having a plurality of openings for exposing a portion of the copper layer.

Therein, at least a portion of the electrically connecting pads have conductive traces extending therefrom.

Therefore, by forming on the carrier the chip-mounting base and the electrically connecting pads, the present invention meets the demands for disposing of conductive traces and increased number of I/O connections. Further, since the copper layer formed on the bottom surfaces of the chip-mounting base and the electrically connecting pads has good bonding with the dielectric layer, solder material in a reflow process can be prevented from permeating into the interface between the chip-mounting base, the electrically connecting pads and the dielectric layer, thereby avoiding the conventional drawback of solder extrusion and enhancing the product yield.

### BRIEF DESCRIPTION OF DRAWINGS

FIGS. 1 to 6 are schematic views showing a method for fabricating a QFN semiconductor package according to the present invention, wherein FIG. 1A is a cross-sectional view taken along a line 1A-1A in FIG. 1B;

FIG. 7 is a cross-sectional view of a conventional QFN semiconductor package; and

FIGS. 8A to 8C′ are cross-sectional views showing another conventional QFN semiconductor package and a method for fabricating the same, wherein FIG. 8C′ is a partially enlarged view of FIG. 8C.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

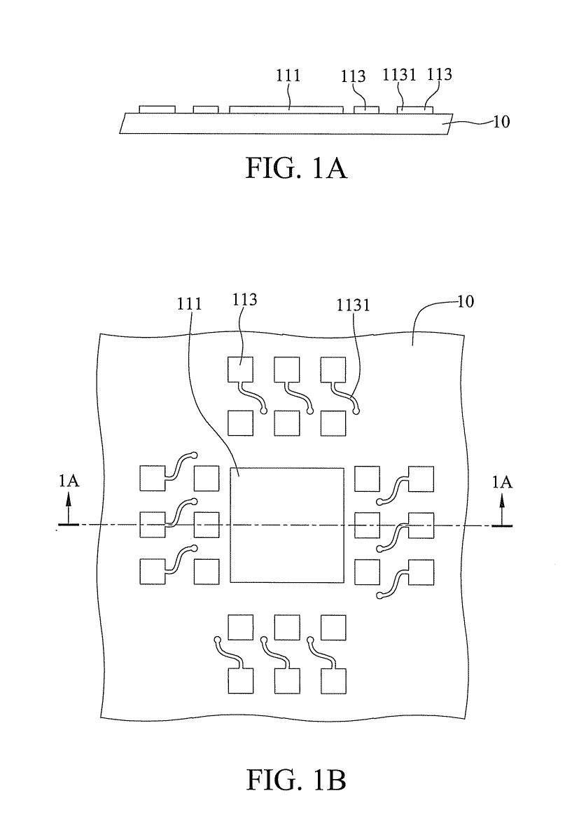

FIGS. 1 to 6 are schematic views showing a QFN semiconductor package and a method for fabricating the same according to the present invention.

Referring to FIGS. 1A and 1B, wherein, FIG. 1A is a cross-sectional view of FIG. 1B, a carrier 10 made of such as copper is prepared, on which a chip-mounting base 111 and a plurality of electrically connecting pads 113 disposed around the periphery of the chip-mounting base 111 are formed. Referring to FIG. 1B, preferably, at least a portion of the electrically connecting pads 113 have conductive traces 1131 extending therefrom. The chip-mounting base 111 and the electrically connecting pads 113 can be formed by electroplating and made of one of Au/Pd/Ni/Pd, Au/Ni/Cu/Ni/Ag, Au/Ni/Cu/Ag, Pd/Ni/Pd, Au/Ni/Au and Pd/Ni/Au. Preferably, a gold layer or palladium layer is located at the bottom surfaces of the chip-mounting base 111 and the electrically connecting pads 113 (where the chip-mounting base 111 and the electrically connecting pads 113 are in contact with the carrier 10).

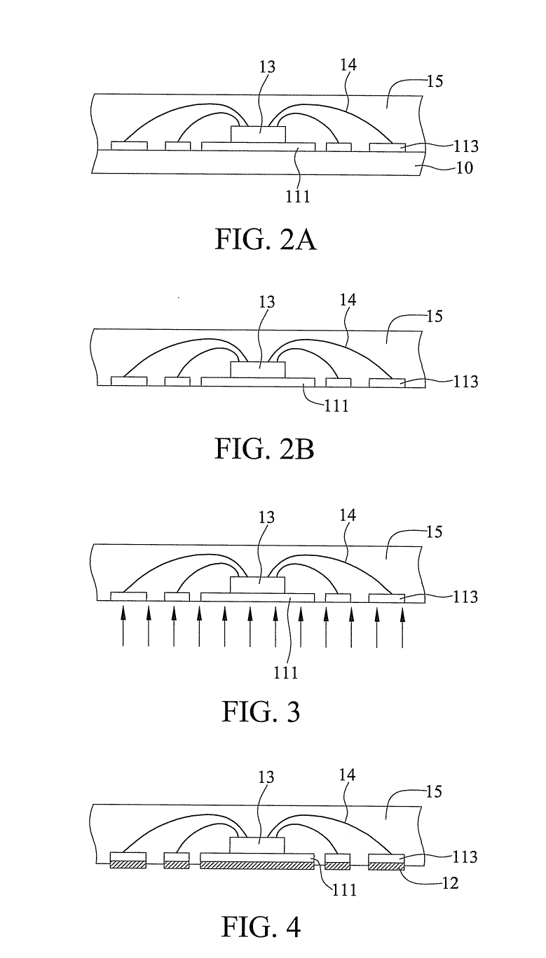

Referring to FIG. 2A, a chip 13 is mounted on the top surface of the chip-mounting base 111 and electrically connected to the electrically connecting pads 113 through a plurality of bonding wires 14. Thereafter, an encapsulant 15 is formed on the carrier 10 to encapsulate the chip-mounting base 111, the electrically connecting pads 113, the chip 13 and the bonding wires 14.

Further referring to FIG. 2B, the carrier 10 is removed by, for example, etching so as to expose the bottom surfaces of the chip-mounting base 111 and the electrically connecting pads 113.

Further referring to FIG. 3 and FIG. 4, a copper layer 12 is formed by electroless plating so as to cover the exposed bottom surfaces of the chip-mounting base 111 and the electrically connecting pads 113.

Referring to FIG. 5, a dielectric layer 16 is formed on the bottom surfaces of the encapsulant 15, the chip-mounting base 111, the electrically connecting pads 113 and the conductive traces 1131, and the dielectric layer 16 has a plurality of openings 161 formed for exposing a portion of the copper layer 12.

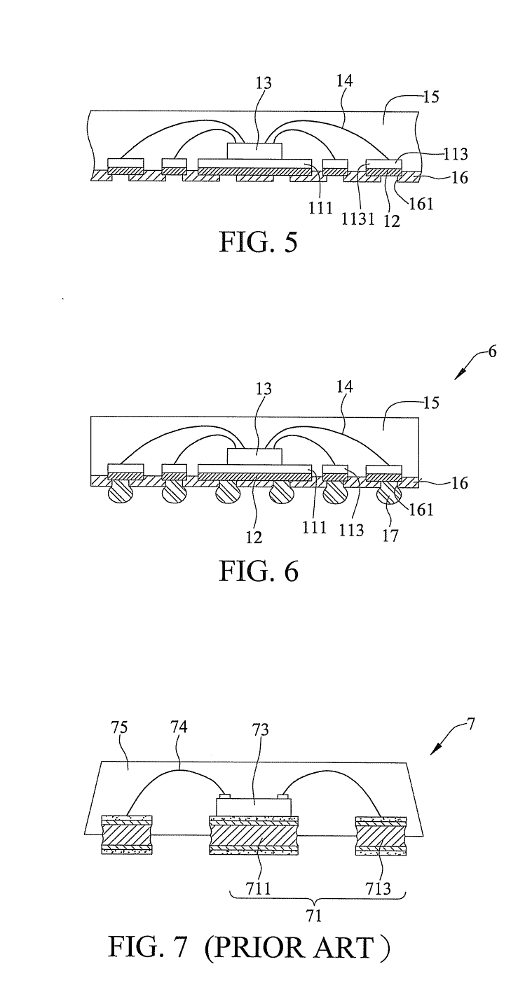

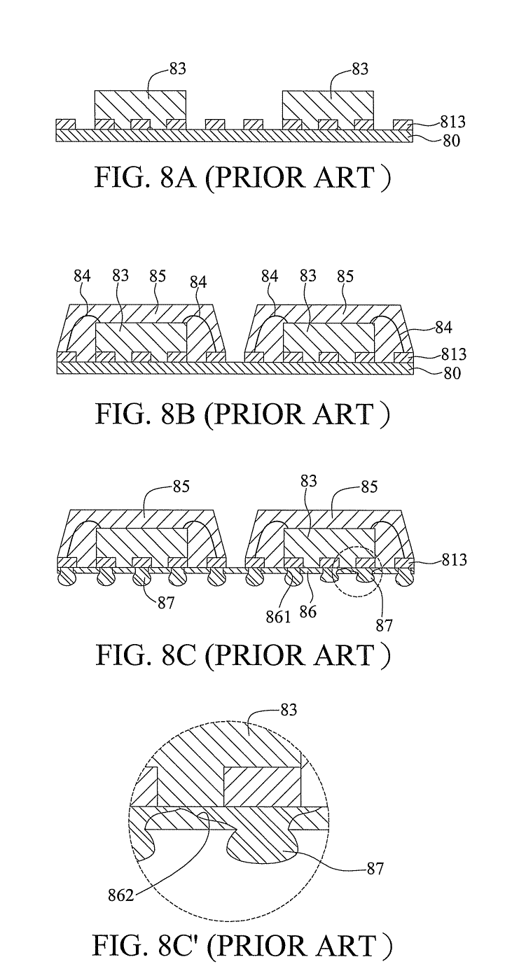

Referring to FIG. 6, a plurality of solder balls 17 is formed in the openings 161 and a cutting process is performed to the encapsulant so as to obtain a single QFN semiconductor package.

The present invention further provides a QFN semiconductor package 6, which comprises: a chip-mounting base 111, a plurality of electrically connecting pads 113, a chip 13, a plurality of bonding wires 14, an encapsulant 15, a copper layer 12, and a dielectric layer 16 with a plurality of openings 161.

In an embodiment, the QFN semiconductor package further comprises a plurality of solder balls 17 formed in the openings 161 of the dielectric layer 16.

The electrically connecting pads 113 are disposed around the periphery of the chip-mounting base 111. Preferably, at least a portion of the electrically connecting pads 113 have conductive traces 1131 extending therefrom. The chip-mounting base 111 and the electrically connecting pads 113 can be made of one or more selected from the group consisting of Au, Pd, Ag, Cu and Ni. For instance, the chip-mounting base 111 and the electrically connecting pads 113 can be made of one of Au/Pd/Ni/Pd, Au/Ni/Cu/Ni/Ag, Au/Ni/Cu/Ag, Pd/Ni/Pd, Au/Ni/Au and Pd/Ni/Au. Preferably, the bottom surfaces of the chip-mounting base 111 and the electrically connecting pads 113 are made of a gold layer or a palladium layer.

The chip 13 is mounted on the top surface of the chip-mounting base 111; a plurality of bonding wires 14 electrically connect to the chip 13 and the electrically connecting pads 113; the encapsulant 15 encapsulates the chip-mounting base 111, the electrically connecting pads 113, the chip 13 and the bonding wires 14 while exposing the bottom surfaces of the chip-mounting base 111 and the electrically connecting pads 113.

The copper layer 12 is formed on the bottom surfaces of the chip-mounting base 111 and the electrically connecting pads 113 by electroless plating. The dielectric layer 16 is formed on the bottom surfaces of the encapsulant 15 and the copper layer 12 and has a plurality of openings 161 formed for exposing a portion of the copper layer 12.

In another embodiment, the copper layer 12 can fully or partially cover the bottom surfaces of the chip-mounting base 111 and the electrically connecting pads 113. In a preferred embodiment, the copper layer 12 is formed in a region where the dielectric layer 16 is to be formed to cover the chip-mounting base 111 and the electrically connecting pads 113 while the region where the copper layer 12 is not formed corresponds to the openings of the dielectric layer 16. In other words, the copper layer 12 isolates the chip-mounting base 111 and the electrically connecting pads 113 from being in contact with the dielectric layer 16.

Therefore, since the copper layer formed on the bottom surfaces of the chip-mounting base and the electrically connecting pads has good bonding with the dielectric layer, solder material in a reflow process can be prevented from permeating into the interface between the chip-mounting base, the electrically connecting pads and the dielectric layer, thereby avoiding solder extrusion and enhancing the product yield.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A method for fabricating a quad flat non-leaded (QFN) semiconductor package, comprising the steps of:
providing a carrier and forming on the carrier a chip-mounting base and a plurality of electrically connecting pads disposed around a periphery of the chip-mounting base;
mounting a chip on a top surface of the chip-mounting base;
electrically connecting the chip and the electrically connecting pads through a plurality of bonding wires;
forming an encapsulant on the carrier to encapsulate the chip-mounting base, the electrically connecting pads, the chip and the bonding wires;
removing the carrier to expose bottom surfaces of the chip-mounting base and the electrically connecting pads;
forming a copper layer to cover the exposed bottom surfaces of the chip-mounting base and the electrically connecting pads; and
forming a dielectric layer on bottom surfaces of the encapsulant and the copper layer and forming a plurality of openings in the dielectric layer for exposing a portion of the copper layer.

2. The method of claim 1, further comprising forming a plurality of solder balls electrically connecting to the copper layer exposed through the openings of the dielectric layer.

3. The method of claim 1, wherein the bottom surfaces of the chip-mounting base and the electrically connecting pads are made of a gold layer or a palladium layer.

4. The method of claim 1, wherein the carrier is a copper carrier.

5. The method of claim 1, wherein the copper layer fully or partially covers the bottom surfaces of the chip-mounting base and the electrically connecting pads.

6. The method of claim 1, wherein the copper layer is formed through electroless plating.

7. The method of claim 1, wherein at least a portion of the electrically connecting pads have conductive traces extending therefrom.

8. A QFN semiconductor package, comprising:
a chip-mounting base;
a plurality of electrically connecting pads disposed around periphery of the chip-mounting base, bottom surfaces of the chip-mounting base and the electrically connecting pads being covered with a copper layer;
a chip mounted on a top surface of the chip-mounting base;
a plurality of bonding wires electrically connecting to the chip and the electrically connecting pads;
an encapsulant encapsulating the chip-mounting base, the electrically connecting pads, the chip and the bonding wires while exposing the copper layer on the bottom surfaces of the chip-mounting base and the electrically connecting pads; and
a dielectric layer formed on bottom surfaces of the encapsulant and the copper layer and having a plurality of openings for exposing a portion of the copper layer.

9. The package of claim 8, further comprising a plurality of solder balls electrically connecting to the copper layer exposed through the openings of the dielectric layer.

10. The package of claim 8, wherein at least a portion of the electrically connecting pads have conductive traces extending therefrom.

11. The package of claim 8, wherein the bottom surfaces of the chip-mounting base and the electrically connecting pads are made of a gold layer or a palladium layer.

12. The package of claim 8, wherein the copper layer fully or partially covers the bottom surfaces of the chip-mounting base and the electrically connecting pads.
